(19) United States
(12) Patent Application Publication
(10) Pub. No.: US 2026/0029576 A1
(43) Pub. Date: Jan. 29, 2026

(54) CHIP STRUCTURE AND SEMICONDUCTOR PACKAGE INCLUDING THE SAME

(71) Applicant: Samsung Electronics Co., Ltd., Suwon-si (KR)

(72) Inventors: Juhyeon Oh, Suwon-si (KR); Seokgeun Ahn, Suwon-si (KR); Daeho Lee, Suwon-si (KR)

(21) Appl. No.: 19/024,434

(22) Filed: Jan. 16, 2025

(30) Foreign Application Priority Data
Jul. 23, 2024 (KR) 10-2024-0097518

(51) Int. Cl. G02B 6/124; H01L 23/48; H01L 25/16; H10F 39/00; H10F 39/95

(52) U.S. Cl. CPC G02B 6/124; H01L 25/167; H10F 39/804; H10F 39/806; H10F 39/95; H01L 23/481

(57) ABSTRACT

A chip structure includes a photonic integrated circuit chip including an optical coupler and a wave-guide extending in a first direction, an electronic integrated circuit chip on the photonic integrated circuit chip, a molding layer on the photonic integrated circuit chip, a first opening and a second opening in the molding layer, the second opening overlapping the first opening in a second direction perpendicular to the first direction, and a first dummy layer spaced apart from the electronic integrated circuit chip in the first direction and inside the first opening, wherein a first width in the first direction of the first opening is less than a second width in the first direction of the second opening.

### CROSS-REFERENCE TO RELATED APPLICATION

This application is based on and claims priority under 35 U. S. C. § 119 to Korean Patent Application No. 10-2024-0097518, filed Jul. 23, 2024, in the Korean Intellectual Property Office, the disclosure of which is incorporated by reference herein in its entirety.

### BACKGROUND

The inventive concept relates to a semiconductor package and a method of manufacturing the same, and particularly, to a chip structure and a semiconductor package including a photonic integrated circuit chip.

Semiconductor packages are often used to improve the function of electronic devices and integrate components. The semiconductor packages may allow various integrated circuits, such as memory chips or logic chips to be mounted on package substrates. Recently, in an environment where data traffic is increasing in data centers and communication infrastructure, semiconductor packages including photonic integrated circuit chips are being studied.

### SUMMARY

The inventive concept provides a chip structure to which an optical signal may be easily received and a semiconductor package including the chip structure.

In addition, the problem to be solved by the inventive concept is not limited to the those mentioned above, and other problems may be clearly understood by those skilled in the art from the description below.

According to an aspect of the inventive concept, there is provided a chip structure including a photonic integrated circuit chip including an optical coupler and a wave-guide extending in a first direction, an electronic integrated circuit chip on the photonic integrated circuit chip, a molding layer on the photonic integrated circuit chip, a first opening and a second opening in the molding layer, the second opening overlapping the first opening in a direction perpendicular to the first direction, and a first dummy layer spaced apart from the electronic integrated circuit chip in the first direction and inside the first opening, wherein a first width in the first direction of the first opening is less than a second width in the first direction of the second opening.

According to an aspect of the inventive concept, there is provided a chip structure including a photonic integrated circuit chip including an optical coupler and a wave-guide extending in a first direction, an electronic integrated circuit chip on the photonic integrated circuit chip, a molding layer on the photonic integrated circuit chip and including an opening therein and comprising a groove area, a first dummy layer in the opening, and spaced apart from the electronic integrated circuit chip in the first direction, the groove at least partially surrounding the first dummy layer, and a connector on the first dummy layer and overlapping the optical coupler in a second direction perpendicular to the first direction.

According to an aspect of the inventive concept, there is provided a semiconductor package including a package substrate, a semiconductor chip on the package substrate, and a chip structure on the package substrate, wherein the chip structure includes a photonic integrated circuit chip including a grating coupler and a wave-guide extending in a first direction, an electronic integrated circuit chip on the photonic integrated circuit chip, a first dummy layer on the photonic integrated circuit chip and spaced apart from the electronic integrated circuit chip in the first direction, a connector on the first dummy layer and overlapping the grating coupler in a second direction perpendicular to the first direction, and a molding layer comprising a first opening in which the first dummy layer is disposed and a second opening overlapping the first opening in the second direction and at least partially surrounding the connector.

### BRIEF DESCRIPTION OF THE DRAWINGS

Embodiments will be more clearly understood from the following detailed description taken in conjunction with the accompanying drawings in which:

FIG. 1 is a schematic plan view of a semiconductor package according to an embodiment;

FIG. 2 is a schematic cross-sectional view of a chip structure according to an embodiment, taken along line I-I′ of FIG. 1;

FIG. 3A is a perspective view of an example of a connector included in a chip structure according to an embodiment;

FIG. 3B is a plan view of an example of a connector included in a chip structure according to an embodiment;

FIG. 4 is a schematic plan view of a portion of a chip structure according to an embodiment;

FIG. 5 is a schematic enlarged view of a portion EX1 of FIG. 2;

FIG. 6 is a schematic cross-sectional view of a chip structure according to an embodiment, taken along line I-I′ of FIG. 1;

FIG. 7 is a schematic cross-sectional view of a chip structure according to an embodiment, taken along line I-I′ of FIG. 1; and

FIGS. 8A, 8B, 8C, 8D, 8E, 8F, and 8G are cross-sectional views shown according to a process order to describe a method of manufacturing a chip structure according to an embodiment.

### DETAILED DESCRIPTION OF THE EMBODIMENTS

Hereinafter, embodiments are described in detail with reference to the accompanying drawings. The same reference numerals are used for the same components in the drawings, and redundant descriptions thereof are omitted. While the embodiments may be variously modified and have various shapes, some embodiments are illustrated in the drawings and described in detail. However, the embodiments are not intended to limit the inventive concept to the disclosed embodiments. It is noted that aspects described with respect to one embodiment may be incorporated in different embodiments although not specifically described relative thereto. That is, all embodiments and/or features of any embodiments can be combined in any way and/or combination.

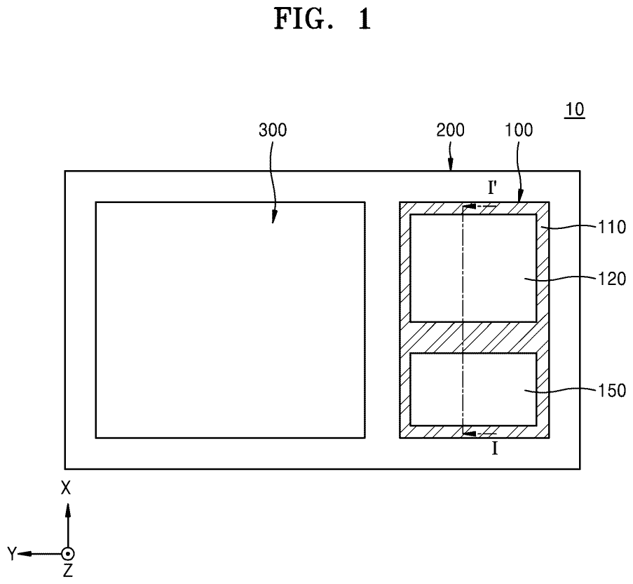

FIG. 1 is a schematic plan view of a semiconductor package 10 according to an embodiment.

Referring to FIG. 1, the semiconductor package 10 may include a package substrate 200, a semiconductor chip 300, and a chip structure 100. The semiconductor package 10 may communicate with an external device through an optical signal.

Hereinafter, unless specifically defined, a direction parallel to an upper surface of the package substrate 200 is referred to as a first horizontal direction (an X direction), a direction vertical to the upper surface of the package substrate 200 is referred to as a vertical direction (a Z direction), and a direction vertical to the first horizontal direction (the X direction) and the vertical direction (the Z direction) may be referred to as a second horizontal direction (the Y direction). A synthesis of the first horizontal direction (the X direction) and the second horizontal direction (the Y direction) is referred to as the horizontal direction.

The package substrate 200 may be an interposer including a substrate and a through via 100_V penetrating or extending through the substrate. For example, the package substrate 200 may be an interposer wherein the substrate includes a glass and the through via 100_V is a through glass via (TGV). However, embodiments are not limited thereto and the package substrate 200 may be an interposer wherein the substrate includes silicon and the through via is a through silicon via (TSV).

In some embodiments, the package substrate 200 may be a redistribution structure including a redistribution pattern and a redistribution insulating layer at least partially surrounding the redistribution pattern.

The redistribution insulating layer may include an insulating substance, such as a photo-imageable dielectric (PID) resin. In some embodiments, the redistribution insulating layer may further include an inorganic filler. In some embodiments, the redistribution insulating layer may have a multilayer structure in which each layer includes the redistribution pattern.

The redistribution pattern may include a redistribution line pattern extending in the horizontal direction and a redistribution via pattern extending from the redirection line pattern in the vertical direction (the Z direction). The redistribution line pattern may be disposed in at least one surface of the upper surface and the lower surface of the redistribution insulating layer or the inside of the redistribution insulating layer. The redistribution via pattern may penetrate or extend through the redistribution insulating layer and be connected to a portion of the redistribution line pattern.

The redistribution pattern may include a conductive material such as copper (Cu), aluminum (Al), silver (Ag), tin (Sn), gold (Au), nickel (Ni), lead (Pb), titanium (Ti), or an alloy thereof.

In some embodiments, the package substrate 200 may be a printed circuit board (PCB) including a core insulating layer including at least one material selected from phenol resin, epoxy resin, and polyimide.

The semiconductor chip 300 may be disposed above the package substrate 200. The semiconductor chip 300 may include an active surface and an inactive surface facing the active surface. In some embodiments, the semiconductor chip 300 may include an application specific integrated circuit (ASIC).

In some embodiments, the semiconductor chip 300 may be mounted on the package substrate 200 such that the active surface faces downward in the Z direction. That is, the semiconductor chip 300 may be mounted on the package substrate 200 such that a connection pad of the semiconductor chip 300 is disposed above the active surface in the Z direction and the connection pad of the semiconductor chip 300 is electrically connected to an upper pad of the package substrate 200.

In some embodiments, a plurality of individual devices of various types may be disposed on the active surface of the semiconductor chip 300. For example, the plurality of individual devices may include a variety of micro electronic devices, for example, a complementary metal-oxide semiconductor (CMOS) transistor, a metal-oxide-semiconductor filed effect transistor (MOSFET), an image sensor such as a system large scale integration (LSI) and a CMOS imaging sensor (CIS), a micro-electro-mechanical system (MEMS), an active device, a passive device, and the like.

The chip structure 100 may be disposed over the package substrate 200. The chip structure 100 may be spaced apart from the semiconductor chip 300 in the horizontal direction (e.g., the Y direction). The chip structure 100 may be electrically connected to the semiconductor chip 300 through the package substrate 200.

For example, the chip structure 100 may receive an optical signal from an external device and convert the received optical signal into an electrical signal so as to input the converted electrical signal to the semiconductor chip 300 through the package substrate 200. An optical fiber module may be detachably coupled to the chip structure 100. The chip structure will be described in detail below.

Since the semiconductor package 10 may communicate with an external device with an optical signal through the chip structure 100, the data processing speed of the semiconductor package 10 may be improved. In addition, the chip structure 100 of the semiconductor package 10 may be separated from the optical fiber module and, when failure occurs in the optical fiber, the optical fiber in the semiconductor package 10 may be replaced.

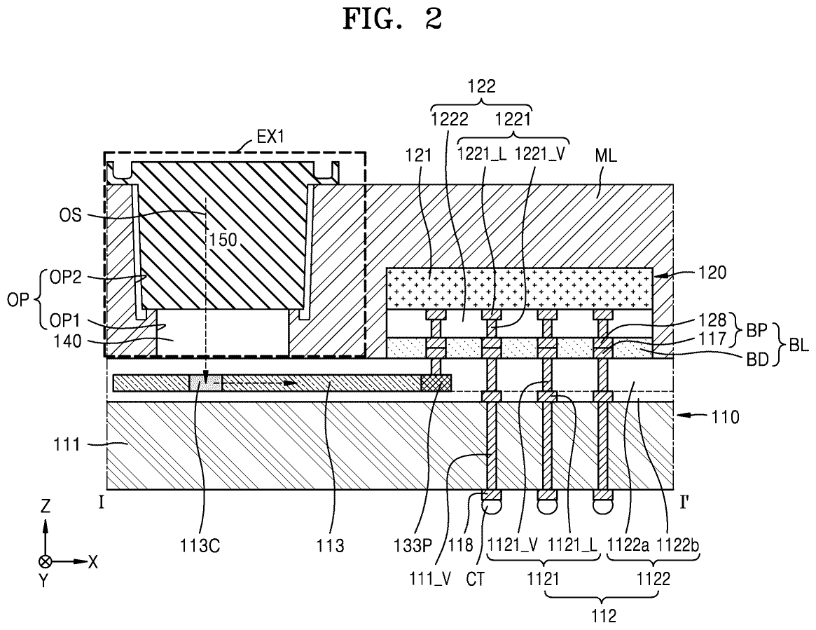

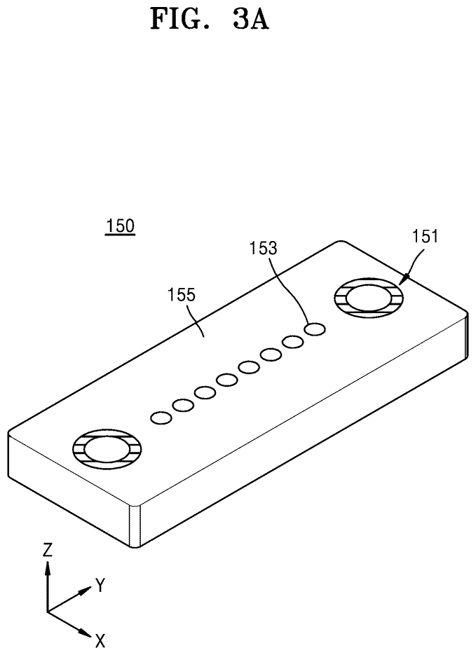

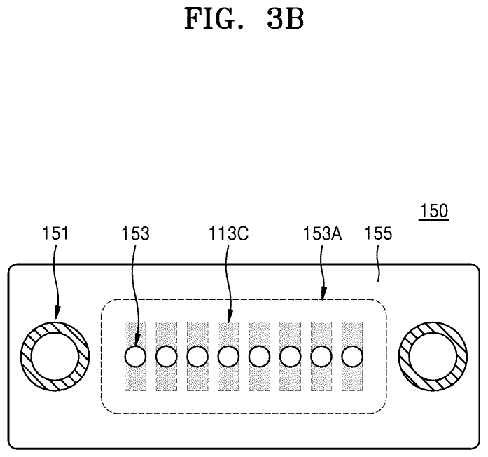

FIG. 2 is a schematic cross-sectional view of the chip structure 100 according to an embodiment, taken along line I-I′ of FIG. 1. FIG. 3A is a perspective view of an example of a connector included in the chip structure according to an embodiment, and FIG. 3B is a plan view of an example of a connector included in the chip structure according to an embodiment.

Referring to FIG. 2, the chip structure 100 may include a photonic integrated circuit (PIC) chip 110, an electronic integrated circuit (EIC) chip 120, a first dummy layer 140, and a connector 150. For example, the optical fiber module may be detachably coupled to the connector 150 of the chip structure 100.

The PIC chip 110 may be disposed on the package substrate 200 (refer to FIG. 1). The PIC chip 110 may be spaced apart from the semiconductor chip 300 (refer to FIG. 1) in the horizontal direction.

For example, a lower pad 118 of the PIC chip 110 may be electrically connected to the upper pad of the package substrate 200 (refer to FIG. 1) through a connection terminal CT. However, the connection method of the PIC chip 110 to the package substrate 200 (refer to FIG. 1) is not limited thereto.

The PIC chip 110 may include a first substrate 111, a first wiring structure 112, a wave-guide 113, and an optical coupler 113C. For example, the first wiring structure 112 and the wave-guide 113 may be disposed over the upper surface of the first substrate 111. For example, the first substrate 111 may include a first through via 111_V extending from the upper surface of the first substrate 111 to the lower surface of the first substrate 111. The first through via 111_V may be electrically connected to the first wiring structure 112.

In some embodiments, the first substrate 111 may include a semiconductor material such as silicon (Si). In other embodiments, the first substrate 111 may include a semiconductor material such as germanium (Ge).

The first wiring structure 112 may include a first wiring pattern 1121 and a first wiring insulating layer 1122 at least partially surrounding the first wiring pattern 1121. The first wiring pattern 1121 may include a first wiring line 1121_L extending in the horizontal direction and a first wiring via 1121_V extending from the first wiring line 1121_L in the vertical direction (the Z direction). The first wiring pattern 1121 may be electrically connected to the first through via 111_V.

The first wiring insulating layer 1122 may be divided into a lower wiring insulating layer 1122b and an upper wiring insulating layer 1122a. In some embodiments, the lower wiring insulating layer 1122b may be an oxide layer such as silicon oxide. The upper wiring insulating layer 1122a may be a dielectric layer including one or more layers such as silicon oxide, silicon nitride, and a combination thereof. In some embodiments, the lower wiring insulating layer 1122b and the upper wiring insulating layer 1122a may have the same material.

The PIC chip 110 may further include a upper pad 117. The upper pad 117 is disposed over the upper surface of the first wiring structure 112 and may be electrically connected to the first wiring pattern 1121.

The wave-guide 113 is a patterned silicon layer and may extend from above the lower wiring insulating layer 1122b in the horizontal direction. For example, the wave-guide 113 may be buried in the first wiring insulating layer 1122. For example, the wave-guide 113 may be disposed over the lower wiring insulating layer 1122b and be at least partially covered by the upper wiring insulating layer 1122a.

In some embodiments, the wave-guide 113 may be a silicon wave-guide including silicon, and the first wiring insulating layer 1122 may be a buried oxide (BOX) layer. Embodiments are not limited thereto and, in some embodiments, the wave-guide 113 may be at least partially covered by an oxide layer different from the first wiring insulating layer 1122.

In some embodiments, the wave-guide 113 may further include an optical coupler 113C. In an embodiment, the optical coupler 113C may be a grating coupler.

The wave-guide 113 may be connected to an optical component 113P. The optical component 113P may convert the optical signal OS to an electrical signal and vice versa. In some embodiments, the optical component 113P may include an optical detector, an optical diode, and a modulator.

In the process of inputting the optical signal OS into the chip structure 100, the optical detector may detect the optical signal OS input to the PIC chip 110. The PIC chip 110 may detect the optical signal OS input through the optical detector and convert the optical signal OS into an electrical signal.

In a process of outputting the optical signal OS by the chip structure 100, the electronic integrated circuit chip 120 may be configured to transmit the electrical signal to the modulator. The modulator may convert the electrical signal to the optical signal OS by inputting a value corresponding to the received electrical signal to light emitted by the optical diode.

The electronic integrated circuit chip 120 may be disposed over the photonic integrated circuit chip 110. The electronic integrated circuit chip 120 may be configured to interconnect the PIC chip 110 with the semiconductor chip 300 (refer to FIG. 1). For example, the electronic integrated circuit chip 120 may convert the electrical signal converted by the PIC chip 110 to match the semiconductor chip 300 (refer to FIG. 1).

In some embodiments, the width of the electronic integrated circuit chip 120 may be less than the width of the PIC chip 110. For example, a portion of the PIC chip 110 may not be covered by the electronic integrated circuit chip 120, i.e., the PIC chip 110 may be free of the electronic integrated circuit chip 120.

The electronic integrated circuit chip 120 may include a second substrate 121 and a second wiring structure 122. The second substrate 121 of the electronic integrated circuit chip 120 may include an active surface and an inactive surface facing the active surface. The second wiring structure 122 may be formed on the active surface of the second substrate 121.

The second substrate 121 may include a semiconductor material such as silicon (Si). In other embodiments, the second substrate 121 may include a semiconductor material such as germanium (Ge).

In some embodiments, the electronic integrated circuit chip 120 may include a plurality of individual devices configured to interface with the PIC chip 110. The plurality of individual devices of the electronic integrated circuit chip 120 may be disposed in the active surface of the second substrate 121. For example, the electronic integrated circuit chip 120 may include CMOS drivers, trans-impedance amplifiers, etc. to perform functions such as controlling high-frequency signaling of the PIC chip 110.

The second wiring structure 122 may include a second wiring pattern 1221 and a second wiring insulating layer 1222 at least partially surrounding the second wiring pattern 1221. The second wiring pattern 1221 may include a second wiring line 1221_L extending in the horizontal direction and a second wiring via 1221_V extending from the second wiring line 1221_L in the vertical direction (the Z direction). The second wiring pattern 1221 may be electrically connected to the plurality of individual devices and the lower pad 128.

In some embodiments, the electronic integrated circuit chip 120 may be disposed over the PIC chip 110 such that the active surface of the second substrate 121 faces the PIC chip 110. For example, the electronic integrated circuit chip 120 may be disposed face down onto the PIC chip 110.

In some embodiments, a bonding layer BL may be disposed between the electronic integrated circuit chip 120 and the PIC chip 110. The bonding layer BL may include a bonding pad BP and a bonding insulating layer BD at least partially surrounding the bonding pad BP. For example, the electronic integrated circuit chip 120 and the PIC chip 110 may be electrically connected to each other by the bonding layer BL disposed between the electronic integrated circuit chip 120 and the PIC chip 110.

In some embodiments, the bonding pad BP of the bonding layer BL may be formed by diffusion bonding through heat of the upper pad 117 of the PIC chip 110 and the lower pad 128 of the electronic integrated circuit chip 120. In the process of forming the bonding pad BP, the bonding insulating layer BD may be formed by diffusion bonding through heat of the insulating layer at least partially surrounding the upper pad 117 of the PIC chip 110 and the insulating layer at least partially surrounding the lower pad 128 of the electronic integrated circuit chip 120.

For example, the electronic integrated circuit chip 120 and the PIC chip 110 may be electrically connected to each other through hybrid bonding. However, embodiments are not limited thereto, and the electronic integrated circuit chip 120 and the PIC chip 110 may be electrically connected to each other by a connection terminal such as a solder ball or an adhesive film such as an anisotropic film ACF, a non-conductive film NCF, and the like.

The first dummy layer 140 electronic integrated circuit chip 120 may be disposed over the PIC chip 110. The first dummy layer 140 may be spaced apart from the electronic integrated circuit chip 120 in the horizontal direction. The optical signal OS may pass through the first dummy layer 140. In some embodiments, the transmittance of the first dummy layer 140 in the infrared wavelength band may be 99% or more. The first dummy layer 140 may include at least one material of silicon and glass.

At least a portion of the first dummy layer 140 may overlap the optical coupler 113C in the vertical direction (e.g., the Z direction). That is, on a plan view, the first dummy layer 140 may overlap the optical coupler 113C.

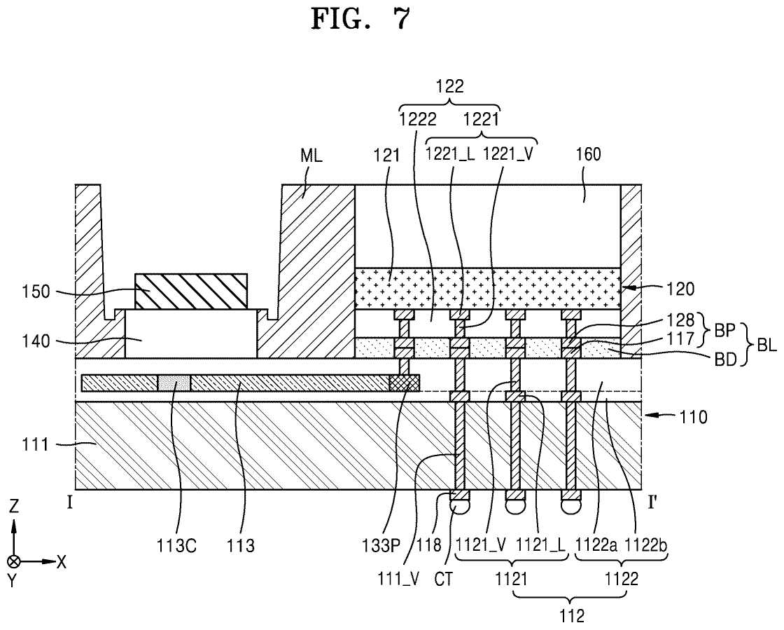

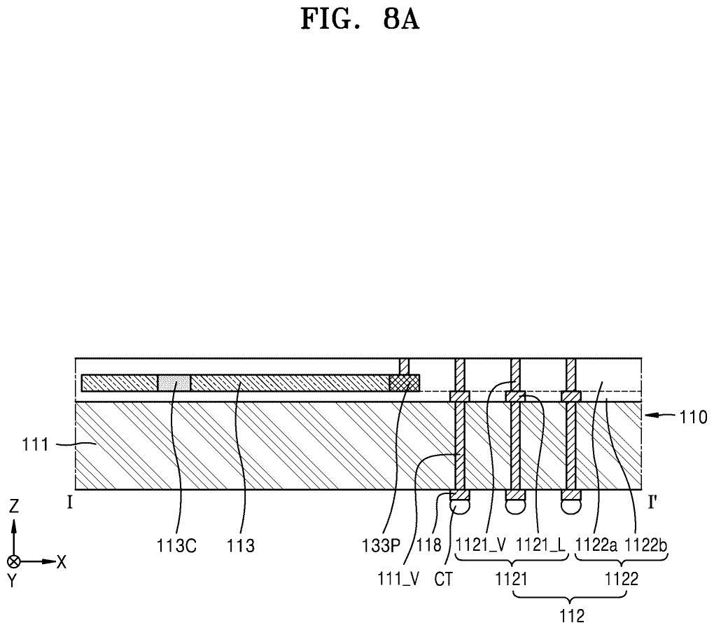

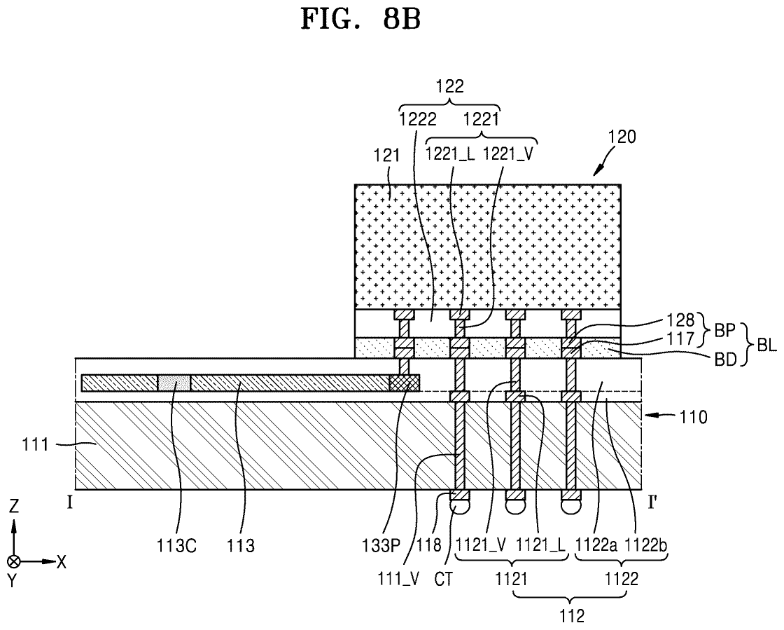

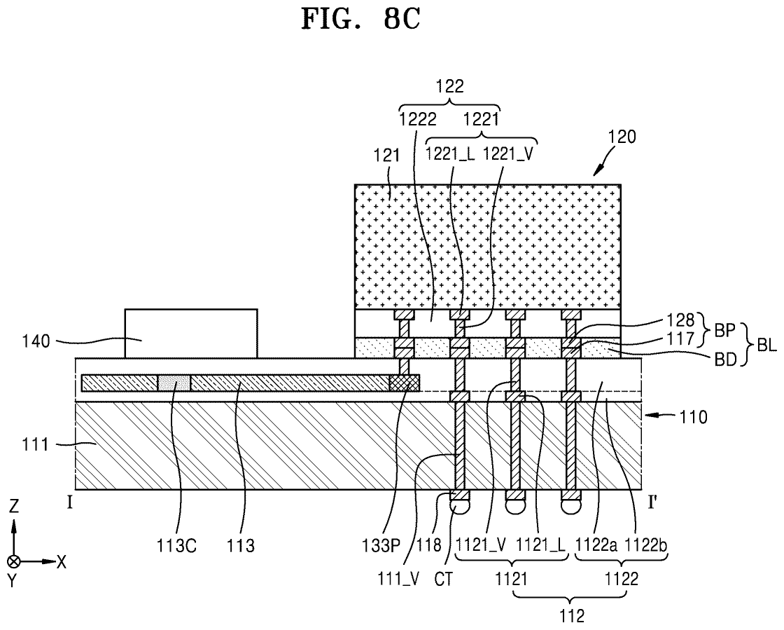

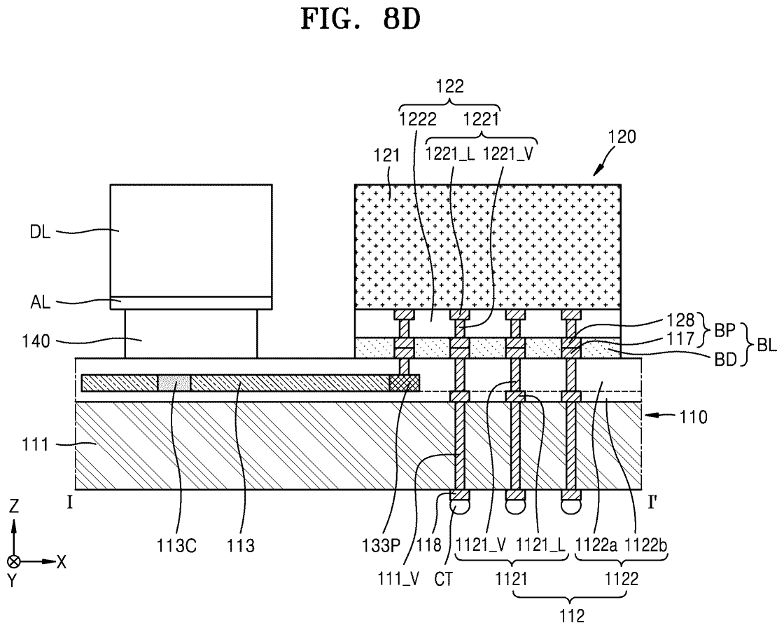

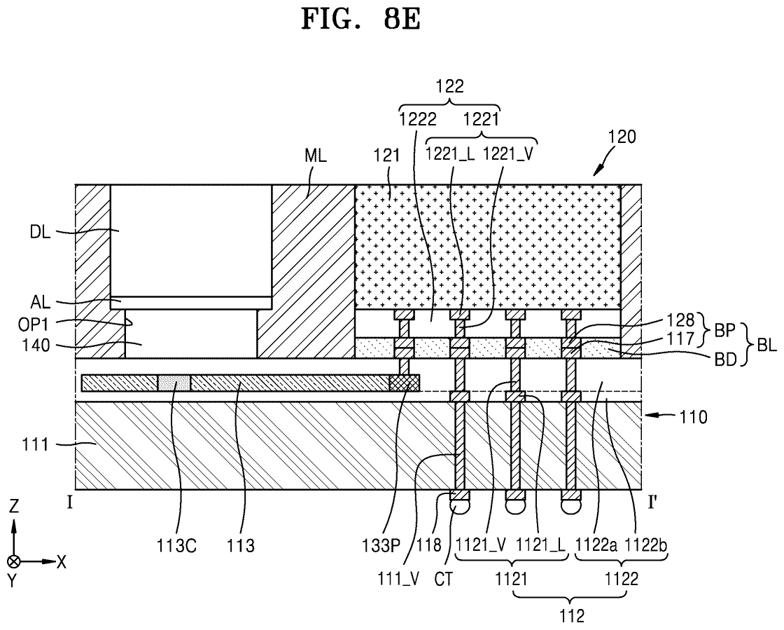

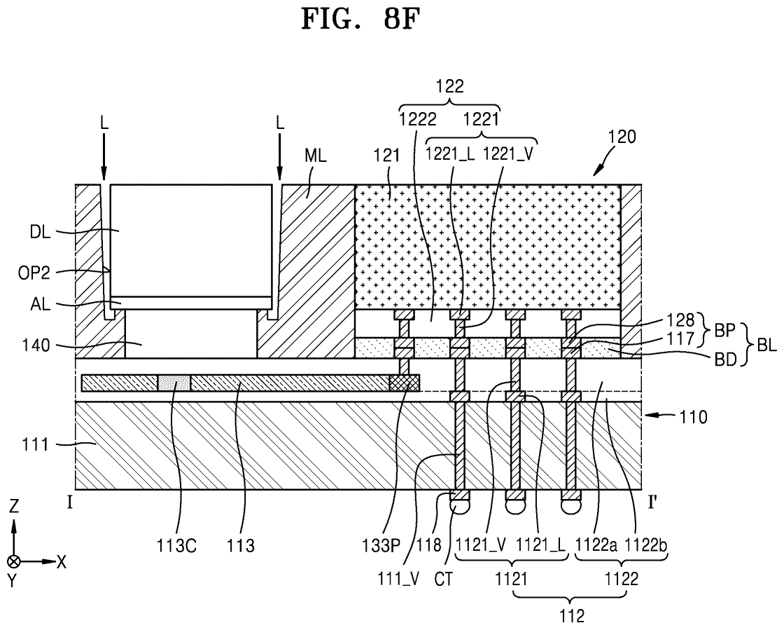

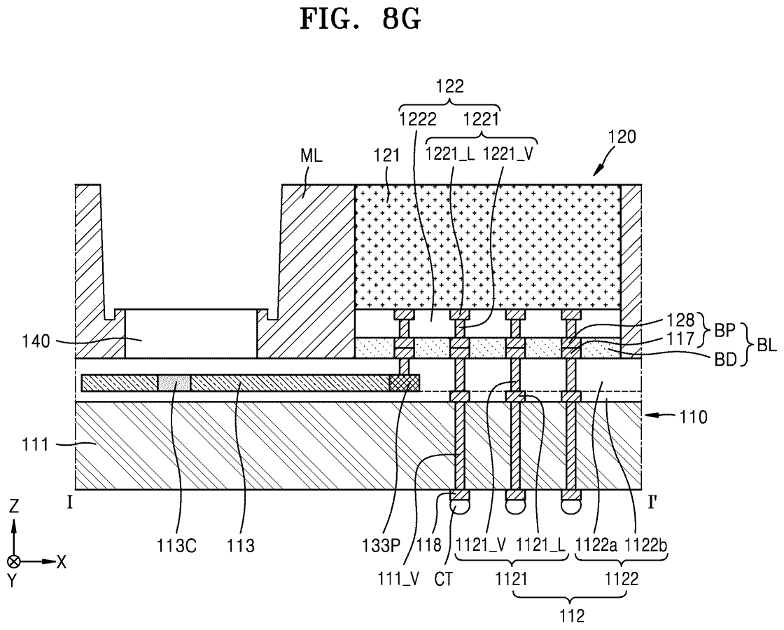

The connector 150 may be disposed on the first dummy layer 140. The connector 150 may be spaced apart from the electronic integrated circuit chip 120 in the horizontal direction. A lower surface of the connector 150 may be in direct contact with an upper surface of the first dummy layer 140. In some embodiments, the width of the lower surface of the connector 150 may be greater than the width of the upper surface of the first dummy layer 140, but the embodiment is not limited thereto. For example, as shown in FIGS. 7 and 8, the width of the lower surface of the connector 150 may be less than the width of the upper surface of the first dummy layer 140.

The connector 150 may be detachably coupled to the optical fiber module in various ways. The connector may be understood as an optical receptacle. The optical fiber module may be disposed over the connector 150. The connector 150 may be configured to transmit the optical signal OS to the PIC chip 110 through the first dummy layer 140 disposed under the connector 150. As shown in FIG. 2, the optical signal OS may be transmitted/received through the connector 150 and the first dummy layer 140 in a direction vertical to the direction in which the wave-guide 113 extends.

The connector 150 may include a structure that may change coupled light in the optical coupler 113C vertically or horizontally. In some embodiments, the connector 150 may include at least one of a prism, mirror, and lens.

Referring to FIGS. 3A and 3B, for example, the connector 150 may include a body portion 155, a fixing portion 151, and a plurality of lenses 153. The body portion 155 may include glass. In this case, as shown in FIG. 3B, the shape of the optical coupler 113C disposed under the connector 150 may be seen through.

The fixing portion 151 may be mechanical ports for fixing the optical fiber module to the connector 150. The fixing portion 151 may be disposed at both ends of the connector 150. The optical fiber module may be stably connected to the connector 150 by using the fixing portion 151.

The plurality of lenses 153 may be a micro lens array (MLA) disposed in the horizontal direction. Each of the plurality of lenses 153 may be connected to an optical fiber included in the optical fiber module connected to the connector 150. The plurality of lenses 153 may overlap the optical coupler 113C of the PIC chip 110 in the vertical direction. In an embodiment, when the optical coupler 113C is a grid coupler, each of the plurality of lenses 153 may be disposed correspondingly to a grating structure of a grating coupler as shown in FIG. 3B. The connector 150 may reduce signal loss of the optical signal OS by including the plurality of lenses 153.

Referring again to FIG. 2, the chip structure 100 may further include a molding layer ML. The molding layer ML may be disposed over the PIC chip 110 and may be on and cover at least a portion of the side surface and the upper surface of the electronic integrated circuit chip 120. In an embodiment, the molding layer ML may cover the upper surface of the electronic integrated circuit chip 120. The molding layer ML may at least partially surround the first dummy layer 140 and the connector 150. The molding layer ML may protect the electronic integrated circuit chip 120 and the connector 150 from the outside.

For example, the molding layer ML may include a dielectric material. The molding layer ML may include an epoxy resin, a polyimide resin, or the like. For example, the molding layer ML may include an epoxy molding compound (EMC).

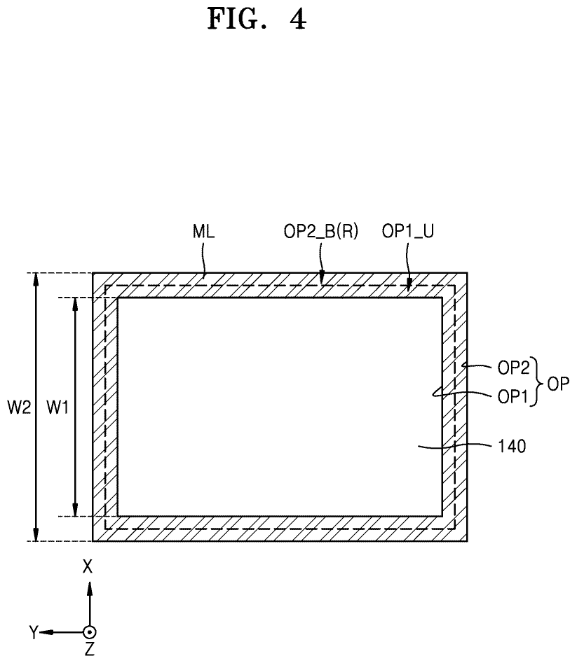

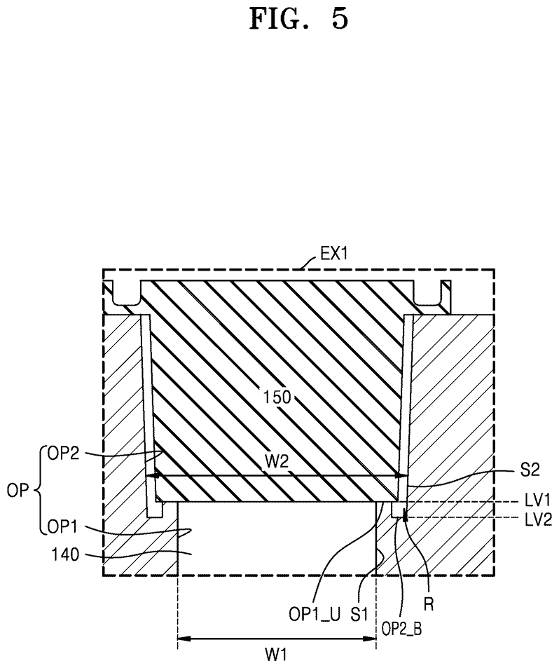

FIG. 4 is a schematic plan view of an area of the chip structure 100 according to an embodiment and illustrates the arrangement relation between the opening OP of the molding layer ML and the first dummy layer 140 on a plan view. FIG. 5 is a schematic enlarged view of an EX1 portion of FIG. 2.

Referring to FIGS. 4 and 5 together with FIG. 2, an opening OP may be defined in the molding layer ML. The opening OP of the molding layer ML may overlap the optical coupler 113C of the PIC chip 110 in the vertical direction. The opening OP of the molding layer ML may expose the upper surface of the first dummy layer 140 and may include a groove area R at least partially surrounding the first dummy layer 140. In other words, the opening OP of the molding layer ML may include the first opening OP1 and a second opening OP2 overlapping the first opening OP1 on a plan view.

The first dummy layer 140 may be disposed inside the first opening OP1 and a first inner side surface S1 of the molding layer ML defining the first opening OP1 may be in direct contact with the side surface of the first dummy layer 140. The connector 150 may be disposed inside the second opening OP2. A second inner side surface S2 of the molding layer ML defining the second opening OP2 may at least partially surround the connector 150.

In some embodiments, the second inner side surface S2 of the molding layer ML defining the second opening OP2 may be tapered. The second inner side surface S2 may be an inclined surface having a predetermined angle from the vertical direction (e.g., the Z direction).

A first horizontal width W1 of the first opening OP1 may be less than a second horizontal width W2 of the second opening OP2 (W1<W2). Although FIG. 4 shows that the first horizontal width W1 and the second horizontal width W2 are widths in the X direction, embodiments are not limited thereto. The first horizontal width W1 and the second horizontal width W2 may be widths in a horizontal direction. That is, on a plan view, the second opening OP2 may be understood to at least partially surround the first opening OP1.

In addition, FIG. 4 illustrates the first opening OP1 and the second opening OP2 are rectangular on a plan view, but embodiments are not limited thereto. For example, the first opening OP1 and the second opening OP2 may have a circular, oval, or various polygonal shapes.

In some embodiments, a second vertical level LV2 of a bottom surface OP2_B of the molding layer ML defining the second opening OP2 may be less than a first vertical level LV1 of an upper surface OP1_U of the molding layer ML defining the first opening OP1 (LV2<LV1). The term “vertical level” used herein refers to the height from the upper surface of the first substrate 111 (refer to FIG. 2) in the vertical direction (the Z direction or the −Z direction).

In some embodiments, the upper surface of the first dummy layer 140 and the upper surface OP1_U of the molding layer ML defining the first opening OP1 may be coplanar. That is, the vertical level of the first dummy layer 140 may be the same as the first vertical level LV1 of the upper surface OP1_U of the molding layer ML defining the first opening OP1. That is, the vertical level of the upper surface of the first dummy layer 140 may be the same as the second vertical level LV2w of the bottom surface OP2_U of the molding layer ML defining the second opening OP2.

At least a portion of the first inner side surface S1 of the molding layer ML defining the first opening OP1 may overlap, in the horizontal direction, at least a portion of the second inner side surface S2 of the molding layer ML defining the second opening OP2.

Accordingly, a groove area R having a depth as much as a difference between the first vertical level LV1 and the second vertical level LV2 may be formed between the first opening OP1 and the second opening OP2. That is, the groove area R described above may be disposed between the first opening OP1 and the second opening OP2.

The chip structure 100 according to various embodiments may include the PIC chip 110 including the optical coupler 113C, and the first dummy layer 140 and the connector 150 that are sequentially stacked in the opening OP of the molding layer ML on the PIC chip 110, and the connector 150 may be connected to the optical fiber module. Since the molding layer ML is not disposed on the optical coupler 113C, the optical signal OS may pass through the first dummy layer 140 and be easily connected to be transmitted/received in a direction vertical to the extending direction of the wave-guide 113, and the optical fiber module may be detachably coupled to the connector.

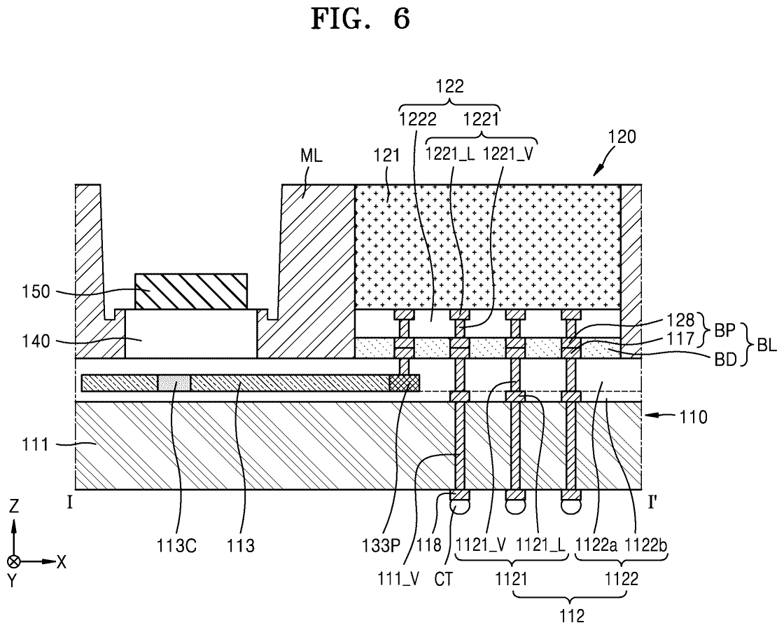

FIG. 6 is a schematic cross-sectional view of the chip structure 100 according to an embodiment, taken along line I-I′ of FIG. 1. Since the same reference numerals in FIGS. 2 and 6 refer to substantially identical or similar components, duplicate descriptions are omitted and differences between FIGS. 2 and 6 are mainly described below.

Unlike FIG. 2 in which the molding layer ML covers the upper surface of the electronic integrated circuit chip 120, referring to FIG. 6, the upper surface of the molding layer ML may be coplanar with the upper surface of the electronic integrated circuit chip 120. The molding layer ML may be in direct contact with the side surface of the electronic integrated circuit chip 120 and may at least partially surround the electronic integrated circuit chip 120, but the upper surface of the electronic integrated circuit chip 120 may be exposed from the molding layer ML. In this regard, since the upper surface of the electronic integrated circuit chip 120 is exposed without being covered by the molding layer ML, heat generated from the electronic integrated circuit chip 120 may be emitted, thereby preventing damage to the chip structure 100.

FIG. 7 is a schematic cross-sectional view of the chip structure 100 according to an embodiment, taken along line I-I′ of FIG. 1. Since the same reference numerals in FIGS. 2 and 7 refer to substantially identical or similar components, duplicate descriptions are omitted and differences between FIGS. 2 and 7 are mainly described below.

Referring to FIG. 7, a second dummy layer 160 may be disposed on the electronic integrated circuit chip 120. The lower surface of the second dummy layer 160 may be in direct contact with the upper surface of the electronic integrated circuit chip 120. The molding layer ML may at least partially surround the side surface of the second dummy layer 160 and the side surface of the electronic integrated circuit chip 120. The molding layer ML may be in direct contact with the side surface of the second dummy layer 160 and the side surface of the electronic integrated circuit chip 120. The molding layer ML may expose the upper surface of the second dummy layer 160. The upper surface of the second dummy layer 160 may be coplanar with the upper surface of the molding layer ML.

When it is difficult to increase the thickness of the electronic integrated circuit chip 120 due to the process or the structure of the chip structure 100, by arranging the second dummy layer 160 on the electronic integrated circuit chip 120, the upper surface of the electronic integrated circuit chip 120 may be exposed from the molding layer ML. The heat generated from the electronic integrated circuit chip 120 may be emitted through the second dummy layer 160. In some embodiments, the second dummy layer 160 may include a material with heat dissipation characteristics. The second dummy layer 160 may include at least one material of silicon and glass. The second dummy layer 160 may include the same material as the first dummy layer 140.

Referring to FIGS. 6 and 7, the width of the connector 150 in the horizontal direction may be less than the width of the first dummy layer 140 in the horizontal direction, and the vertical level of the upper surface of the connector 150 may be less than the vertical level of the upper surface of the molding layer ML. Embodiments are not limited thereto, and the width of the connector 150 in the horizontal direction may be less than the width of the first dummy layer 140 in the horizontal direction, and the vertical level of the upper surface of the connector 150 may be the same as or greater than the vertical level of the upper surface of the molding layer ML. That is, the thickness, size, etc. of the connector 150 may be adjusted as needed.

FIGS. 8A, 8B, 8C, 8D, 8E, 8F, and 8G are cross-sectional views shown according to a process order to describe a method of manufacturing the chip structure 100 according to an embodiment.

Particularly, FIGS. 8A, 8B, 8C, 8D, 8E, 8F, and 8G are cross-sectional views for describing an example of the process of manufacturing the chip structure 100 shown in FIG. 6 in sequential order. Since the same reference numerals in FIGS. 8A, 8B, 8C, 8D, 8E, 8F, and 8G refer to substantially the same or similar components, for convenience of description, duplicate descriptions are omitted.

Referring to FIGS. 8A and 8B, the PIC chip 110 may be manufactured and the electronic integrated circuit chip 120 may be attached onto the PIC chip 110.

The PIC chip 110 may include the first substrate 111, the first wiring structure 112, and the wave-guide 113. The wave-guide 113 and the first wiring structure 112 may be disposed over the upper surface of the first substrate 111. In some embodiments, the wave-guide 113 may be disposed inside the first wiring structure 112. The wave-guide 113 may include the optical coupler 113C.

The electronic integrated circuit chip 120 may include the second substrate 121 and the second wiring structure 122. The electronic integrated circuit chip 120 may be attached face down onto the PIC chip 110 such that the second wiring structure 122 of the electronic integrated circuit chip 120 faces the PIC chip 110.

In some embodiments, the electronic integrated circuit chip 120 and the PIC chip 110 may be coupled to each other through hybrid bonding. For example, the electronic integrated circuit chip 120 and the PIC chip 110 may be electrically connected to each other by the bonding layer BL disposed between the electronic integrated circuit chip 120 and the PIC chip 110. The method of connecting the electronic integrated circuit chip 120 to the PIC chip 110 is not limited thereto.

For example, the bonding layer BL may include the bonding pad BP and the bonding insulating layer BD. The bonding pad BP may be formed by diffusion bonding through heat of the lower pad 128 of the electronic integrated circuit chip 120 and the upper pad 117 of the PIC chip 110.

Referring to FIGS. 8C and 8D, the first dummy layer 140, an adhesive layer AL, and a third dummy layer DL may be formed on the PIC chip 110. The first dummy layer 140 may overlap the optical coupler 113C in the vertical direction, and the third dummy layer DL may be attached to the upper surface of the first dummy layer 140 through the adhesive layer AL. As shown in FIG. 8D, the horizontal width of the third dummy layer DL may be greater than the horizontal width of the first dummy layer 140.

Referring to FIG. 8E, the molding layer ML may be formed over the PIC chip 110. The molding layer ML may be formed by using at least one of a chemical vapor deposition (CVD) process, a mold process, and a spin coating process. The molding layer ML may at least partially surround a side surface of the first dummy layer 140, a side surface of the third dummy layer DL, and a side surface of the electronic integrated circuit chip 120. The molding layer ML may be in direct contact with the side surface of the first dummy layer 140, the side surface of the third dummy layer DL, and the side surface of the electronic integrated circuit chip 120. The inner side surface (e.g., the first inner side surface S1 of FIG. 5) of the molding layer ML in contact with the first dummy layer 140 may define the first opening OP1 of the molding layer ML.

Referring to FIGS. 8F and 8G, a laser L may be irradiated on the upper surface of the molding layer ML to remove at least a portion of the molding layer ML adjacent to the third dummy layer DL and separate the adhesive layer AL from the first dummy layer 140. Referring to FIG. 8F, before separating the third dummy layer DL and the adhesive layer AL from the first dummy layer 140, the laser L may be irradiated on the upper surface of the molding layer ML to form the second opening OP2. The inner side surface (e.g., the second inner side S2 of FIG. 5) of the molding layer ML defining the second opening OP2 may be tapered.

As described above in FIG. 8D, by forming the horizontal width of the third dummy layer DL to be greater than the horizontal width of the first dummy layer 140, the component disposed below the third dummy layer DL, such as the first dummy layer 140, may be prevented from being damaged by the laser L irradiated for forming the second opening OP2.

Accordingly, referring to FIGS. 8E to 8G, the first horizontal width W1 (refer to FIG. 5) of the first opening OP1 may be less than the second horizontal width W2 (refer to FIG. 5) of the second opening OP2.

In addition, the second vertical level LV2 (refer to FIG. 5) of the bottom surface OP2_B (refer to FIG. 5) of the molding layer ML defining the second opening OP2 may be less than the vertical level of the upper surface of the first dummy layer 140 so as to separate the third dummy layer DL and the adhesive layer AL from the first dummy layer 140. Accordingly, the groove area R (refer to FIG. 5) may be formed between the first opening OP1 and the second opening OP2.

If, without using the first dummy layer 140, the adhesive layer AL, the laser is irradiated on the molding layer ML formed in the area overlapping the optical coupler 113C in the vertical direction to remove a portion of the molding layer ML and the third dummy layer DL, the PIC chip 110 may be damaged. In some embodiments, by forming the opening OP of the molding layer ML on the optical coupler 113C by suing the first dummy layer 140, the adhesive layer AL, and the third dummy layer DL, the PIC chip 110 may be prevented from being damaged by a laser.

Referring to FIGS. 8G and 6, the connector 150 may be disposed inside the second opening OP2 from which the third dummy layer DL and the adhesive layer AL are removed. The connector 150 may overlap the optical coupler 113C in the vertical direction. Particularly, if the optical coupler 113C is a grating coupler, the connector 150 may be disposed inside the second opening OP2 such that each of the plurality of lenses 153 is aligned correspondingly to the grating structure of the optical coupler 113C.

Subsequently, the optical fiber module may be disposed on the connector 150. According to the embodiment, since the optical coupler 113C overlaps the opening OP of the molding layer ML in the vertical direction, and the first dummy layer 140 and the connector 150 are disposed between the optical coupler 113C and the optical fiber module, the optical signal OS may be easily connected to be transmitted/received in a direction vertical to the extending direction of the wave-guide 113.

The inventive concept has been described with reference to the embodiment shown in the drawing, but the descriptions are only examples, and those of ordinary skill in the art may understand that various modifications and equivalent embodiments may be possible.

While the inventive concept has been particularly shown and described with reference to embodiments thereof, it will be understood that various changes in form and details may be made therein without departing from the spirit and scope of the following claims.

What is claimed is:

1. A chip structure comprising:
a photonic integrated circuit chip comprising an optical coupler and a wave-guide extending in a first direction;
an electronic integrated circuit chip on the photonic integrated circuit chip;
a molding layer on the photonic integrated circuit chip;
a first opening and a second opening in the molding layer, the second opening overlapping the first opening in a second direction perpendicular to the first direction; and
a first dummy layer spaced apart from the electronic integrated circuit chip in the first direction and inside the first opening,
wherein a first width in the first direction of the first opening is less than a second width in the first direction of the second opening.

2. The chip structure of claim 1, wherein the first dummy layer overlaps the optical coupler in the second direction.

3. The chip structure of claim 1, wherein a bottom surface of the molding layer is closer in the second direction to the photonic integrated circuit chip than an upper surface of the first dummy layer.

4. The chip structure of claim 1, wherein the molding layer covers at least a portion of the electronic integrated circuit chip and the first dummy layer.

5. The chip structure of claim 1, wherein the width of the first opening in the first direction is less than the width of the second opening in the first direction.

6. The chip structure of claim 5, wherein an inner side surface of the molding layer defining the second opening is tapered.

7. The chip structure of claim 1, wherein a transmittance of the first dummy layer in an infrared wavelength band is 99% or more.

8. The chip structure of claim 1, further comprising a connector on the first dummy layer inside the second opening and overlapping the optical coupler in the second direction.

9. The chip structure of claim 8, wherein the optical coupler is a grating coupler, and
the connector comprises a plurality of lenses corresponding to a grating structure in the grating coupler.

10. The chip structure of claim 1, wherein the molding layer covers an upper surface of the electronic integrated circuit chip.

11. The chip structure of claim 1, wherein an upper surface of the molding layer is coplanar with an upper surface of the electronic integrated circuit chip.

12. The chip structure of claim 1, further comprising a second dummy layer on the electronic integrated circuit chip, wherein the molding layer is in contact with a side surface of the electronic integrated circuit chip and a side surface of the second dummy layer.

13. A chip structure comprising:
a photonic integrated circuit chip comprising an optical coupler and a wave-guide extending in a first direction;
an electronic integrated circuit chip on the photonic integrated circuit chip;
a molding layer on the photonic integrated circuit chip and including an opening therein and comprising a groove area;
a first dummy layer in the opening and spaced apart from the electronic integrated circuit chip in the first direction, the groove area at least partially surrounding the first dummy layer; and
a connector on the first dummy layer and overlapping the optical coupler in a second direction perpendicular to the first direction.

14. The chip structure of claim 13, wherein the opening in the molding layer comprises a first opening in contact with the first dummy layer and a second opening at least partially surrounding the connector, and
wherein the groove area is between the first opening and the second opening.

15. The chip structure of claim 14, wherein a second width in the first direction of the second opening is greater than a first width in the first direction of the first opening.

16. The chip structure of claim 14, wherein a bottom surface of the molding layer defining an outline of the second opening is closer in the second direction to the photonic integrated circuit chip than an upper surface of the molding layer defining an outline of the first opening.

17. The chip structure of claim 13, wherein the first dummy layer comprises silicon, glass, or a combination of silicon and glass.

18. A semiconductor package comprising:
a package substrate;
a semiconductor chip on the package substrate; and
a chip structure on the package substrate,
wherein the chip structure comprises:
a photonic integrated circuit chip comprising a grating coupler and a wave-guide extending in a first direction;
an electronic integrated circuit chip on the photonic integrated circuit chip;
a first dummy layer on the photonic integrated circuit chip and spaced apart from the electronic integrated circuit chip in the first direction;
a connector on the first dummy layer and overlapping the grating coupler in a second direction perpendicular to the first direction; and
a molding layer comprising a first opening in which the first dummy layer is disposed and a second opening overlapping the first opening in the second direction and at least partially surrounding the connector.

19. The semiconductor package of claim 18, wherein an upper surface of the molding layer is coplanar with an upper surface of the electronic integrated circuit chip.

20. The semiconductor package of claim 18, wherein the chip structure further comprises a second dummy layer on the electronic integrated circuit chip, and
wherein an upper surface of the molding layer is coplanar with an upper surface of the second dummy layer.
